(19) United States
(12) Patent Application Publication
(10) Pub. No.: US 2025/0105194 A1
(43) Pub. Date: Mar. 27, 2025

(54) METHOD FOR FORMING CONDUCTIVE BLOCKS, A SEMICONDUCTOR PACKAGE AND A METHOD FOR FORMING THE SAME

(71) Applicant: JCET STATS ChipPAC Korea Limited, Incheon (KR)

(72) Inventors: SeungHyun LEE, Incheon (KR); SangHoon LEE, Incheon (KR); DoYeon PARK, Gyeonggi-do (KR); SangJun PARK, Busan (KR); JaeKyung JEON, Incheon (KR)

(21) Appl. No.: 18/896,961

(22) Filed: Sep. 26, 2024

(30) Foreign Application Priority Data
Sep. 27, 2023 (CN) 202311264312.9

(51) Int. Cl. H01L 23/00; H01L 23/31; H01L 23/538; H01L 23/552; H01L 25/18

(52) U.S. Cl. CPC H01L 24/24; H01L 23/3128; H01L 23/5384; H01L 23/552; H01L 24/16; H01L 25/18; H01L 2224/16165; H01L 2224/24141; H01L 2224/24225; H01L 2924/37001

(57) ABSTRACT

A method for forming conductive blocks on a package substrate, a semiconductor package and a method for forming the same is provided. The method for forming conductive blocks on a package substrate comprises: providing a package substrate with multiple sets of conductive pads formed thereon; depositing a solder material onto the package substrate to form solder bumps on the multiple sets of conductive pads; attaching multiple conductive blocks onto the package substrate, wherein each of the multiple conductive bloc aligned with one of the multiple sets of conductive pads; loading the package substrate on a bottom chase with the multiple conductive blocks facing upward; and pressing, with a top chase, the conductive blocks against the bottom chase to reshape the solder bumps and horizontally align top surfaces of the multiple conductive blocks with each other.

### TECHNICAL FIELD

The present application generally relates to semiconductor packaging technology, and more particularly, to a method for forming conductive blocks, a semiconductor package and a method for forming the same.

### BACKGROUND OF THE INVENTION

The semiconductor industry is constantly faced with complex integration challenges as consumers want their electronics to be smaller, faster and higher performance with more and more functionalities packed into a single device. In recent years, semiconductor packages are fabricated into smaller sizes to bring about higher density of electronic components. Typically, the semiconductor packages may include key functional modules, such as semiconductor chips and interconnection structures. However, it is noted that certain interconnection formation processes, such as stacking multiple layers of solder balls in a single through hole for higher interconnect structures, may be complicated and not cost effective. Also, such complicated process may adversely affect the yield of the semiconductor packages incorporating such interconnection structures.

Therefore, a need exists for a method for forming conductive blocks in a semiconductor package with a simple process and an improved yield.

### SUMMARY OF THE INVENTION

An objective of the present application is to provide a method for forming conductive blocks in a semiconductor package with a simple process and an improved yield.

According to an aspect of the present application, a method for forming conductive blocks on a package substrate is provided. The method comprises: providing a package substrate with multiple sets of conductive pads formed thereon; depositing a solder material onto the package substrate to form solder bumps on the multiple sets of conductive pads; attaching multiple conductive blocks onto the package substrate, wherein each of the multiple conductive blocks is aligned with one of the multiple sets of conductive pads; loading the package substrate on a bottom chase with the multiple conductive blocks facing upward; and pressing, with a top chase, the conductive blocks against the bottom chase to reshape the solder bumps and horizontally align top surfaces of the multiple conductive blocks with each other.

According to another aspect of the present application, a semiconductor package and a method for forming the same is provided. The method comprises: providing a package substrate having a front surface and back surface, wherein multiple sets of conductive pads are formed on the front surface of the package substrate; depositing a solder material onto the front surface of the package substrate to form solder bumps on the multiple sets of conductive pads; attaching an electronic component and multiple conductive blocks onto the front surface of the package substrate, wherein each of the multiple conductive blocks is aligned with one of the multiple sets of conductive pads, and the multiple conductive blocks are thicker than electronic component; loading the package substrate on a bottom chase with the front surface of the package substrate facing upward; and pressing, with a top chase, the conductive blocks against the bottom chase to reshape the solder bumps and horizontally align top surfaces of the multiple conductive blocks with each other; forming a molding material between the top chase and the front surface of the package substrate to encapsulate the multiple conductive blocks and the electronic component but expose the top surfaces of the multiple conductive blocks; and depositing a solder material on the top surfaces of the multiple conductive blocks to form solder bumps thereon.

It is to be understood that both the foregoing general description and the following detailed description are exemplary and explanatory only, and are not restrictive of the invention. Further, the accompanying drawings, which are incorporated in and constitute a part of this specification, illustrate embodiments of the invention and together with the description, serve to explain the principles of the invention.

### BRIEF DESCRIPTION OF DRAWINGS

The drawings referenced herein form a part of the specification. Features shown in the drawing illustrate only some embodiments of the application, and not of all embodiments of the application, unless the detailed description explicitly indicates otherwise, and readers of the specification should not make implications to the contrary.

FIGS. 1A to 1G illustrate various steps of a method for forming a semiconductor package according to an embodiment of the present application.

FIGS. 2A and 2B illustrate respective scanning electron microscope (SEM) images of conductive blocks and underneath solder bumps of a semiconductor package sample before and after a pressing step.

### DETAILED DESCRIPTION OF THE INVENTION

The following detailed description of exemplary embodiments of the application refers to the accompanying drawings that form a part of the description. The drawings illustrate specific exemplary embodiments in which the application may be practiced. The detailed description, including the drawings, describes these embodiments in sufficient detail to enable those skilled in the art to practice the application. Those skilled in the art may further utilize other embodiments of the application, and make logical, mechanical, and other changes without departing from the spirit or scope of the application. Readers of the following detailed description should, therefore, not interpret the description in a limiting sense, and only the appended claims define the scope of the embodiment of the application.

In this application, the use of the singular includes the plural unless specifically stated otherwise. In this application, the use of “or” means “and/or” unless stated otherwise. Furthermore, the use of the term “including” as well as other forms such as “includes” and “included” is not limiting. In addition, terms such as “element” or “component” encompass both elements and components including one unit, and elements and components that include more than one subunit, unless specifically stated otherwise. Additionally, the section headings used herein are for organizational purposes only, and are not to be construed as limiting the subject matter described.

As used herein, spatially relative terms, such as “beneath”, “below”, “above”, “over”, “on”, “upper”, “lower”, “left”, “right”, “vertical”, “horizontal”, “side” and the like, may be used herein for ease of description to describe one element or feature's relationship to another element(s) or feature(s) as illustrated in the Figures. The spatially relative terms are intended to encompass different orientations of the device in use or operation in addition to the orientation depicted in the Figures. The device may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

As mentioned above, an approach to form higher interconnection structures in a semiconductor package such as in a mold cap of such semiconductor package is stacking multiple layers of solder balls in a single through hole. However, such approach may be complicated in process. As an alternative approach, preformed conductive blocks such as e-bars, which have multiple conductive pillars built in a single block, may be mounted in a through hole or cavity on a package substrate to form a thicker interconnection structure. The inventors of the present application noticed that semiconductor packages incorporating preformed conductive blocks have a relatively lower yield and are low in reliability. After an investigation of samples of the semiconductor packages, the inventors have identified that there may be a significant height difference between two or more preformed conductive blocks on a same package substrate, due to a difference in the size and height of solder bumps that mount conductive blocks on the package substrate. To address this issue, a new method for attaching conductive blocks on a substrate is provided, which introduces a pressing step to obtain solder bumps with a substantially uniform height. The method can be used in forming a semiconductor package such as a double side molded (DSM) package, as a portion of the steps of the forming process.

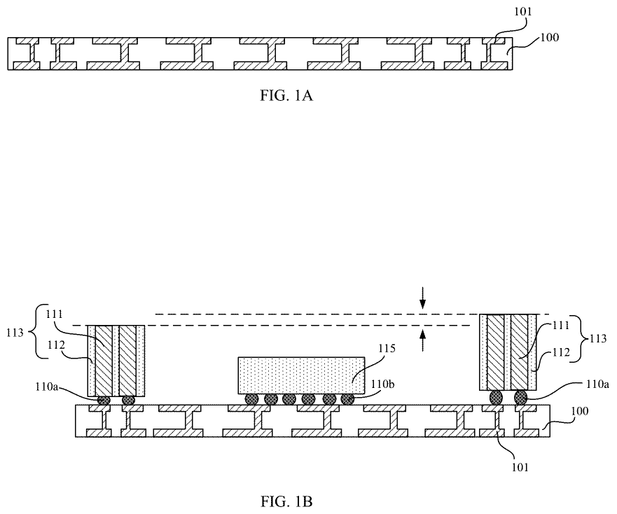

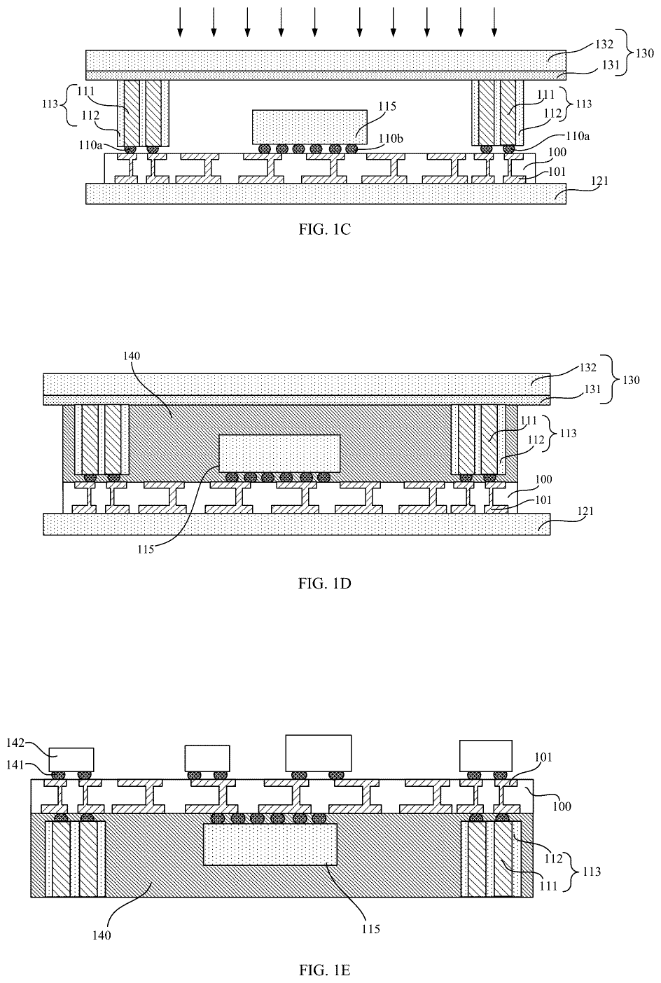

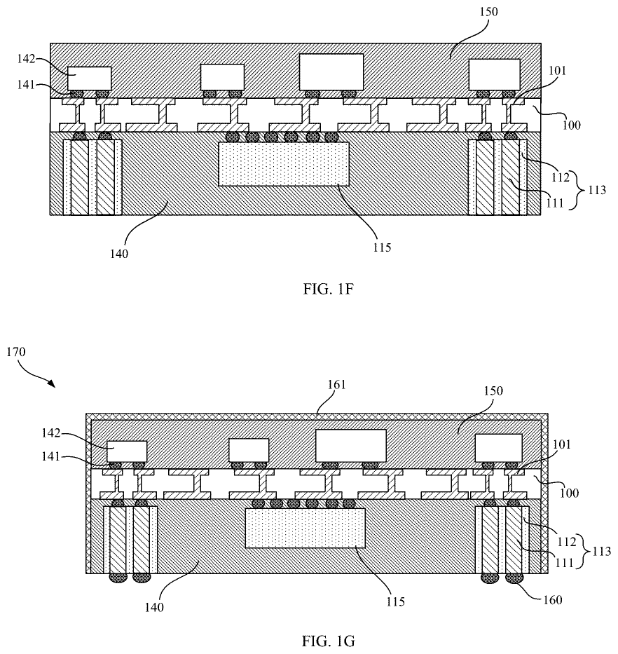

FIGS. 1A to 1G illustrate various steps of a method for forming a semiconductor package according to an embodiment of the present application. In the following, the method will be described with reference to FIGS. 1A to 1G in more details.

As shown in FIG. 1A, a package substrate 100 is provided with embedded interconnect wires 101. The package substrate 100 includes a front surface and a back surface, which are opposite to each other. The front surface of the package substrate 100 may serve as a platform where electronic component(s) and conductive blocks can be mounted. In some embodiments, the semiconductor package may be a DSM package, and accordingly, the back surface may also serve as another platform where electronic component(s) may be mounted. Multiple sets of conductive pads (not shown) can be formed on the front surface and/or back surface of the package substrate 100 for the mounting of the electronic components and the conductive blocks. It can be appreciated that the multiple sets of conductive pads may be exposed portions of interconnect wires 101 formed within the package substrate 100.

As shown in FIG. 1B, a solder material is deposited onto the front surface of the package substrate 100 to form a plurality of solder bumps 110a and 110b on the multiple sets of conductive pads. The solder bump material can be Al, Sn, Ni, Au, Ag, lead (Pb), bismuth (Bi), Cu, or combinations thereof, with an optional flux solution.

Next, an electronic component 115 is attached onto the front surface of the package substrate 100 via the solder bumps 110b, thus forming electrical connection between the interconnect wires 101 and the electronic component 115. In some embodiments, the electronic component 115 may be semiconductor chips or smaller semiconductor packages. It can be appreciated that more electronic components 115 may be mounted onto the front surface. Furthermore, multiple conductive blocks 113 are also attached onto the front surface of the package substrate 100 via the solder bumps 110a, thus forming electrical connection between interconnect wires 101 and the conductive blocks 113. The conductive blocks 113 may be e-bar blocks that include built in conductive pillars 111 such as copper pillars and an insulative base material separating the copper pillars from each other. Two conductive blocks 113 may be mounted on the front surface at different locations, for example, at two opposite sides of the electronic component 115. In the embodiment, the multiple conductive blocks 113 are thicker than the electronic component 115. In this way, the semiconductor package may be electrically connected with other external electronic devices via the conductive blocks 113 while, at the same time, keeping the electronic component 115 isolated from other devices. In some embodiments, the conductive blocks 113 and the electronic component 115 can be attached onto the front surface of the package substrate 100 simultaneously, while in some other embodiments, the conductive blocks 113 may be attached onto the front surface of the package substrate 100 before or after the electronic component 115 is attached.

As mentioned above, each of the multiple conductive blocks 113 is aligned with one of the multiple sets of conductive pads. In this example, the conductive blocks 113 are positioned at two opposite sides of the electronic component 115, which are separated apart with a relatively long distance. However, it can be appreciated that the electronic component 115 and the conductive blocks 113 may be attached onto the front surface of the package substrate 100 with a different distance and arrangement. Furthermore, more conductive blocks may be attached onto the front surface, depending on the actual needs of the semiconductor package.

Still referring to FIG. 1B, the conductive blocks 113 may include e-bar blocks. In this example, each e-bar block further includes multiple conductive pillars 111 and a dielectric layer 112 surrounding the conductive pillars 111. The dielectric layer 112 includes materials such as an insulative polymeric material or composite. To be more specific, bottom surfaces of the conductive pillars 111 are exposed from a bottom surface of the dielectric layer 112 for contacting the solder bumps 110a. Similarly, top surfaces of the conductive pillars 111 are exposed from a top surface of the dielectric layer 112 for electrical contact purpose. To be more specific, conductive pads may be formed on the conductive pillars 111, and solder bumps may be disposed on the conductive pads subsequently for contacting an external device. In some embodiments, the conductive pillars 111 in some conductive blocks 113 are electrically connected with each other. In some other embodiments, the conductive pillars 111 in some conductive blocks 113 are not electrically connected with each other but electrically isolated from each other for separate electrical paths. Furthermore, the number of the conductive pillars 111 included in each conductive block 113 may vary according to actual needs of the semiconductor package.

As mentioned above, the conductive blocks 113 at different positions on the package substrate 100 may have different heights due to the unevenness of the front surface of the package substrate 100, the nonuniformity of the forming process of the solder bumps and the inconformity of the attaching process of the conductive blocks 113 onto the package substrate 100. For example, the heights of the solder bumps 110a under the e-bar block 113 in the left of the electronic component 115 may be different from the heights of the solder bumps 110a under the e-bar block 113 in the right of the electronic component 115, rendering a height difference between the top surfaces of the conductive blocks 113. A pressing process may be conducted to address this issue.

As shown in FIG. 1C, the package substrate 100 is loaded on a bottom chase 121 with the front surface of the package substrate 100 facing upward. The bottom chase 121 may be used for placing the package substrate 100 and providing upward supporting forces when the conductive blocks 113 are pressed against the bottom chase 121. In a preferred embodiment, a length of the bottom chase 121 in a horizontal direction may be greater than that of the package substrate 100 to provide sufficient and balanced forces to support the package substrate 100.

Next, the conductive blocks 113 are pressed against the bottom chase 121 with a top chase 130 to reshape the solder bumps 110a. In this example, all of the multiple conductive blocks 113 are in contact with the same surface of the top chase 130 to receive forces simultaneously from the top chase 130. During the pressing process, the solder bumps 110a may be substantially flattened, for example, from a circular shape to an oval shape or even a disk shape, thereby resulting in reduced distances from the top surfaces of the conductive blocks 113 to the front surface of package substrate 100 in a controlled way. After the pressing step, the top surfaces of the multiple conductive blocks 113 are horizontally aligned with each other, which allows for enhanced uniformity of the structures of the conductive blocks 113. It can be appreciated that, the amount of reduction in the height of the solder bumps may be different, depending on the original heights of the solder bumps. The higher the original height is, the more compression or reduction in height is. Also, since the conductive blocks 113, especially the conductive pillars 111 inside, may have a stiffness greater than that of the solder bumps 110a, the pressing process may not reshape the conductive blocks 113.

In the embodiment shown in FIG. 1C, the top chase 130 may include a base plate 132 and a flexible film 131, and the flexible film 131 is in contact with the top surfaces of the multiple conductive blocks 113 during the pressing step. The flexible film 131 may serve as a release film, which provides a buffer between the base plate 132 and the conductive blocks 113 to protect the conductive blocks 113 from potential damage during the pressing step. The flexible film 131 material may include foamed plastic, rubber or the like. In some embodiments, the flexible film 131 can be multi-layered structure which provides a more delicate buffer between the base plate 132 and the conductive blocks 113. In some other embodiments, the flexible material can be omitted, where the base plate 132 may directly contacting the surfaces of the multiple conductive blocks 113. In this example, since the multiple conductive blocks 113 are thicker than the electronic component 115, the electronic component 115 is not affected when the multiple conductive blocks 113 are pressed by the top chase 130. Accordingly, when the pressing step is completed, a gap may exist between the top surface of the electronic component 115 and the bottom surface of the top chase 130 such that the electronic component 115 can be fully encapsulated subsequently.

Furthermore, in some embodiments, the bottom surface of the top chase 130 is an extended flat surface. In some other embodiments, the top chase may include a cavity with a bottom surface within the top chase, and the top surfaces of the multiple conductive blocks are in contact with the bottom surface of the cavity. In some examples, the cavity of the top chase may serve as an injection molding chamber for a subsequent molding process. In other words, both the pressing process and the molding process may be implemented by a single set of tools.

It can be appreciated that since the pressing step may reduce the heights of the solder bumps 110a, respective cross sections of the solder bumps in the horizontal direction may expand for some extent. However, the pressing step may be implemented that the solder bumps 110a on each set of conductive pads are reshaped but not connected with each other to avoid potential short circuit risks. Therefore, during the pressing step, the pressure and forces applied onto the top chase 130 should be determined based on the space and distance between adjacent solder bumps. In some embodiments, a stopper may be provided between the top and bottom chases to limit a maximum distance the top chase can move toward the bottom chase.

It can be appreciated that the pressing step may be implemented when a reflowing of the solder bumps is being implemented. Also, the solder bumps may exhibit deformable characteristics which may be reshaped by external forces.

Next, as shown in FIG. 1D, a molding material is formed between the top chase 130 and the front surface of the package substrate 100 to form a first mold cap 140 to encapsulate the multiple conductive blocks 113 and the electronic component 115. In some embodiments, the first mold cap 140 is formed using a molding process such as a film-assisted molding (FAM) process, which covers the top and lateral surfaces of the electronic component 115 and the lateral surfaces of the conductive blocks 113 for encapsulation. The molding material is first liquefied by heat and pressure, and then forced into a closed mold cavity (e.g., the cavity in the top chase) and held there under additional heat and pressure until all material is solidified. The FAM process enables easy release of the encapsulated package from the chases since the molding material contacts the assisting films instead of the metal mold chase. Also, the films may function as soft cushions, resulting in less wear of mold parts. The mold material used in the FAM process may include very sticky type and liquid silicone materials. It can be appreciated that the assisting films may include the flexible film 131 of the top chase 130 when the top chase 130 is used for both pressing and molding. In some other embodiments, another set of mold chases may be used for the molding process, instead of the top chase 130 and bottom chase 121 that are used in the pressing process. Moreover, in some other embodiments, the first mold cap 140 can also be formed using other molding technologies.

As shown in FIG. 1E, the substrate 100 and the various components thereon may be removed from the top chase 130 and the bottom chase 121. The substrate 100 may then be flipped over for further attachment of other components on its back surface. In particular, one or more electronic components 142 are attached onto the back surface of the package substrate 100. The electronic components 142 may be electrically connected with interconnect wires 101 embedded in the package substrate 100 via a plurality of solder bumps 141. In this way, the electronic components 142 mounted on the back surface of the package substrate 100, the electronic component 115 mounted on the front surface of the package substrate 100 and the conductive blocks 113 can be electrically connected with each other, forming an integrated electronic package device. The electronic package may be further connected with external circuits via the conductive blocks 113.

In some embodiments, the electronic components 142 include various types of electronic modules, such as semiconductor chips, resistors, capacitors or the like. The electronic components 142 may have different sizes. In some other embodiments, it can be appreciated that the electronic components 142 may be arranged and sized according to actual needs of the semiconductor package.

As shown in FIG. 1F, a molding material is formed on the back surface of the package substrate 100 to form a second mold cap 150 that encapsulates the one or more electronic components 142 on the back surface. Similar as the molding process for the first mold cap 140 illustrated in FIG. 1D, the second mold cap 150 may be formed using a molding process such as an injection molding process, which covers respective front surfaces of the electronic components 142 for encapsulation. Therefore, a double side molded package is formed with the electronic components attached and packaged on both the front surface and the back surface of the package substrate 100. In some embodiments, the solder bumps may be reflowed before the second mold cap 150 is formed.

As shown in FIG. 1G, a shielding layer 161 is formed at least outside the molding material on the back surface of the package substrate 100. The shielding layer 161 may help to protect the other parts of the semiconductor package from electromagnetic interferences. In some embodiments, the shielding layer 161 may extend to the other surfaces (e.g., lateral surfaces) of the mold caps, and/or other structures adjacent to the mold caps. In some embodiments, the package substrate 100 may be singulated into smaller units before or after the formation of the shielding layer 161.

Next, a solder material is deposited on the top surfaces of the multiple conductive blocks 113 to form solder bumps 160 thereon for attaching other external electronic devices, thereby forming the semiconductor package 170.

In some embodiments, the semiconductor package 170 can be applied in any semiconductor devices which desire conductive blocks 113 with uniform structures and improved yield, such as in high-sensitive sensors, precise integrated circuit devices or the like.

It can be appreciated that the process of pressing the solder bumps 110a may be implemented in various other applications, other than the semiconductor package 170. For example, the method may not include the process of attaching electronic components 142 or 115 onto the front surface and the back surface of the package substrate 100, which thereby only forms conductive blocks 113 on a package substrate 100. The top surfaces of the multiple conductive blocks 113 are aligned horizontally with each other.

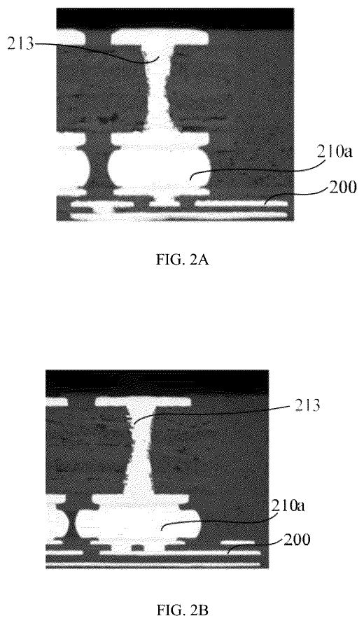

FIGS. 2A and 2B illustrate respective scanning electron microscope (SEM) images of a conductive block and an underneath solder bump of a semiconductor package sample before and after a pressing step. During the pressing step, the conductive block is pressed against a bottom chase to reshape the solder bump and horizontally align a top surface of the conductive block with top surface(s) of other conductive blocks (not shown).

As shown in FIG. 2A, the solder bump 210a between the conductive block 213 and a conductive pattern 200 in a package substrate is disc shaped with a relatively greater height. However, as shown in FIG. 2B, after the pressing step, the solder bump 210a is apparently flattened due to the pressure applied against the bottom chase, and thus the solder bump 210a has a relatively smaller height. Accordingly, a distance from the top surface of the conductive block 213 to the front surface of the conductive pattern 200, i.e., the front surface of a package substrate, is reduced in a controlled way. Although the cross section of the solder bump 210a expands due to the pressing step, it is not in contact with an adjacent solder bump and thus no short circuit issue may occur. Furthermore, it can be seen that the conductive block 213, especially the conductive wires therein, may not change significantly in shape and size.

While the exemplary method for forming a semiconductor package of the present application is described in conjunction with corresponding figures, it will be understood by those skilled in the art that modifications and adaptations to the method for forming a semiconductor package may be made without departing from the scope of the present invention.

Various embodiments have been described herein with reference to the accompanying drawings. It will, however, be evident that various modifications and changes may be made thereto, and additional embodiments may be implemented, without departing from the broader scope of the invention as set forth in the claims that follow. Further, other embodiments will be apparent to those skilled in the art from consideration of the specification and practice of one or more embodiments of the invention disclosed herein. It is intended, therefore, that this application and the examples herein be considered as exemplary only, with a true scope and spirit of the invention being indicated by the following listing of exemplary claims.

1. A method for forming conductive blocks on a package substrate, comprising:
providing a package substrate with multiple sets of conductive pads formed thereon;
depositing a solder material onto the package substrate to form solder bumps on the multiple sets of conductive pads;
attaching multiple conductive blocks onto the package substrate, wherein each of the multiple conductive blocks is aligned with one of the multiple sets of conductive pads;
loading the package substrate on a bottom chase with the multiple conductive blocks facing upward; and
pressing, with a top chase, the conductive blocks against the bottom chase to reshape the solder bumps and horizontally align top surfaces of the multiple conductive blocks with each other.

2. The method of claim 1, wherein the top chase comprises a base plate and a flexible film, and the flexible film is in contact with the top surfaces of the multiple conductive blocks during the pressing step.

3. The method of claim 1, wherein the conductive blocks are e-bar blocks.

4. The method of claim 1, wherein the solder bumps on each set of conductive pads are reshaped but not connected with each other after the pressing step.

5. A method for forming a semiconductor package, comprising:
providing a package substrate having a front surface and a back surface, wherein multiple sets of conductive pads are formed on the front surface of the package substrate;
depositing a solder material onto the front surface of the package substrate to form solder bumps on the multiple sets of conductive pads;
attaching an electronic component and multiple conductive blocks onto the front surface of the package substrate, wherein each of the multiple conductive blocks is aligned with one of the multiple sets of conductive pads, and the multiple conductive blocks are thicker than electronic component;
loading the package substrate on a bottom chase with the front surface of the package substrate facing upward; and
pressing, with a top chase, the conductive blocks against the bottom chase to reshape the solder bumps and horizontally align top surfaces of the multiple conductive blocks with each other;
forming a molding material between the top chase and the front surface of the package substrate to encapsulate the multiple conductive blocks and the electronic component but expose the top surfaces of the multiple conductive blocks; and
depositing a solder material on the top surfaces of the multiple conductive blocks to form solder bumps thereon.

6. The method of claim 5, wherein before the step of depositing a solder material on the top surfaces of the multiple conductive blocks, the method further comprises:
attaching one or more electronic components onto the back surface of the package substrate; and
forming a molding material on the back surface of the package substrate to encapsulate the one or more electronic components.

7. The method of claim 6, further comprising:
forming a shielding layer at least outside the molding material on the back surface of the package substrate.

8. The method of claim 5, wherein the top chase comprises a base plate and a flexible film, and the flexible film is in contact with the top surfaces of the multiple conductive blocks during the pressing step.

9. The method of claim 5, wherein the conductive blocks are e-bar blocks.

10. The method of claim 5, wherein the solder bumps on each set of conductive pads are reshaped but not connected with each other after the pressing step.

11. A semiconductor package which is formed using the method of claim 5.
